(19) United States
(12) Patent Application Publication
(10) Pub. No.: US 2026/0354193 A1
(43) Pub. Date: Nov. 5, 2026

(54) SEAL RING BPM LAYOUT CONTROL FOR REDUCING PEELING

(71) Applicant: Taiwan Semiconductor Manufacturing Co., Ltd., Hsinchu (TW)

(72) Inventors: Yu-Sheng Lin, Zhubei City (TW); Kai-Xin Liu, Taipei (TW); Yang-Chih Hsueh, Hsinchu (TW); Yan-Zuo Tsai, Hsinchu (TW); Yung-Chi Lin, Su-Lin City (TW); Tzu-Hsin Chang, Hsinchu (TW); Chen-Sheng Lin, Taoyuan City (TW); Kuo-Chiang Ting, Hsinchu (TW)

(21) Appl. No.: 19/341,513

(22) Filed: Sep. 26, 2025

Related U.S. Application Data
(60) Provisional application No. 63/798,709, filed on May 2, 2025.

(51) Int. Cl. H10W 42/00; H10W 72/90; H10W 80/00

(52) U.S. Cl. CPC H10W 42/00; H10W 72/9445; H10W 80/312; H10W 80/327

(57) ABSTRACT

A method includes forming a plurality of dielectric layers, forming a seal ring comprising a plurality of metal rings, each extending into one of the plurality of dielectric layers, forming a plurality of metal lines and vias in the plurality of dielectric layers, wherein the plurality of metal lines and vias are in an inner region encircled by the seal ring, and forming a plurality of seal ring bond pads over the seal ring. The plurality of seal ring bond pads have a first pad density. The method further includes forming a plurality of inner bond pads in the inner region. At least parts of the plurality of inner bond pads are electrically connected to the plurality of metal lines and vias. The plurality of inner bond pads have a second pad density lower than the first pad density.

### PRIORITY CLAIM AND CROSS-REFERENCE

This application claims the benefit of the following provisionally filed U.S. Patent application: Application No. 63/798,709, filed on May 2, 2025, and entitled “Seal Ring Bond Pad Layout;” which application is hereby incorporated herein by reference.

### BACKGROUND

Integrated circuit packages may have a plurality of package components such as device dies and package substrates bonded together to increase the functionality and integration level. Due to the differences between different materials of the plurality of package components, warpage may occur. The warpage may cause non-bond issues, and some conductive features that are intended to be bonded to each other are not bonded, resulting in circuit failure. These issues need to be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7A, 7B, 8-12, 13A, and 13B illustrate the cross-sectional views of intermediate stages in the formation of a package in accordance with some embodiments.

FIGS. 14A, 14B, and 15 illustrate the top views of seal rings in accordance with some embodiments.

FIGS. 16 - 25 illustrate the layouts of bond pads in top dies in accordance with some embodiments.

FIG. 26 illustrates the layout of bond pads on a plurality of seal rings in accordance with some embodiments.

FIG. 27 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A die including bond pads with increased pad density and the method of forming the same are provided. In accordance with some embodiments, a seal ring is formed in a device die. The seal ring encircles an inner region of the die. Inner bond pads are formed in the inner region. The inner bond pads have a first pad density. Dummy bond pads (alternatively referred to as seal ring bond pads) are formed directly over and joined to the seal ring. The seal ring bond pads have a second pad density higher than the first pad density. The device die may be bonded to a package component, with the seal ring bond pads being bonded to the bond pads of the package components. By increasing the pad density of the seal ring bond pads, the bond strength in peripheral regions of the device die is improved, and non-bonds are reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

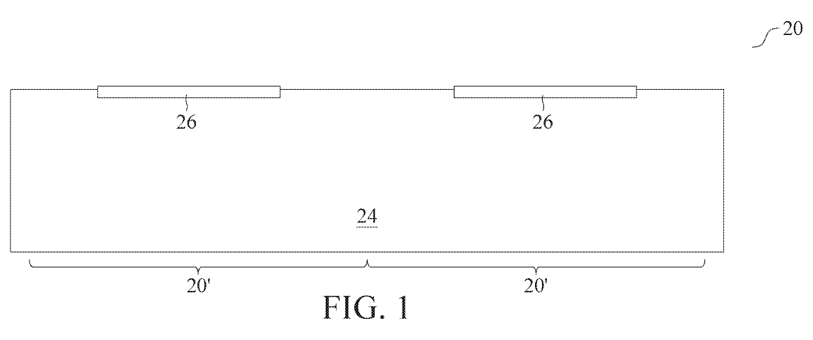

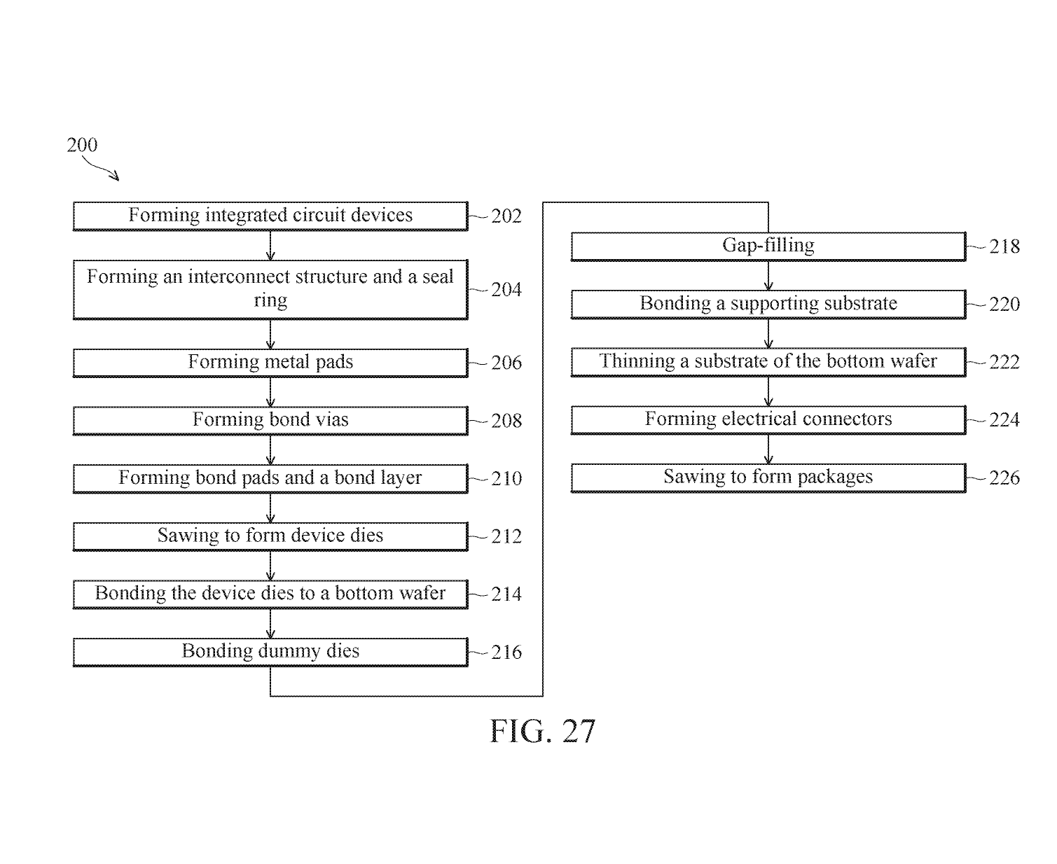

FIGS. 1-12, 13A and 13B illustrate the cross-sectional views of intermediate stages in the formation of a package in accordance with some embodiments. The corresponding processes are also reflected schematically in the process flow shown in FIG. 27.

FIG. 1 illustrates a cross-sectional view of an initial structure of package component 20. In accordance with some embodiments, package component 20 is or comprises a device wafer including active devices and possibly passive devices, which are represented as integrated circuit devices 26. The corresponding package component 20 may include a plurality of device dies 20’ (also referred to as dies or device dies) therein.

In accordance with alternative embodiments, package component 20 is an interposer wafer, which is free from active devices, and may or may not include passive devices. In accordance with yet alternative embodiments, package component 20 is or comprises a package substrate strip, which includes a core-less package substrate or a cored package substrate with a core therein.

In accordance with yet alternative embodiments, package component 20 is a reconstructed wafer including discrete device dies and an encapsulant encapsulating the device dies therein. In subsequent discussion, a device wafer is used as an example of package component 20, and package component 20 may also be referred to as wafer 20. The embodiments of the present disclosure may also be applied on interposer wafers, packages, package substrates, etc.

In accordance with some embodiments, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, a III-V compound semiconductor such as GaAsP, AlInAs, AlGaAs, GaInAs, GaInP, GaInAsP, or the like. Semiconductor substrate 24 may also be a bulk semiconductor substrate or a Semiconductor-On-Insulator (SOI) substrate. Shallow Trench Isolation (STI) regions (not shown) may be formed in semiconductor substrate 24 to isolate the active regions in semiconductor substrate 24. Although not shown, through-vias may (or may not) be formed to extend into semiconductor substrate 24, wherein the through-vias are used to electrically inter-couple the features on opposite sides of wafer 20.

In accordance with some embodiments, wafer 20 includes integrated circuit devices 26, which are formed on the top surface of semiconductor substrate 24. The respective process is illustrated as process 202 in the process flow 200 as shown in FIG. 27. Integrated circuit devices 26 may include Complementary transistors, resistors, capacitors, diodes, and the like in accordance with some embodiments. The details of integrated circuit devices 26 are not illustrated herein. In accordance with alternative embodiments, wafer 20 is used for forming interposers (which are free from active devices), and substrate 24 may be a semiconductor substrate or a dielectric substrate.

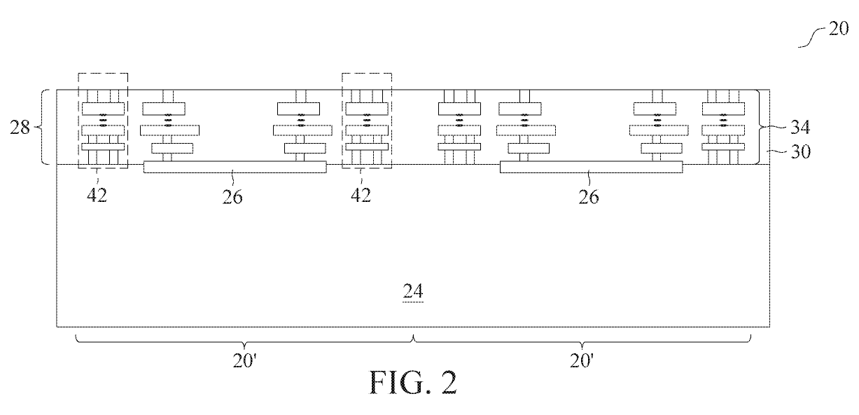

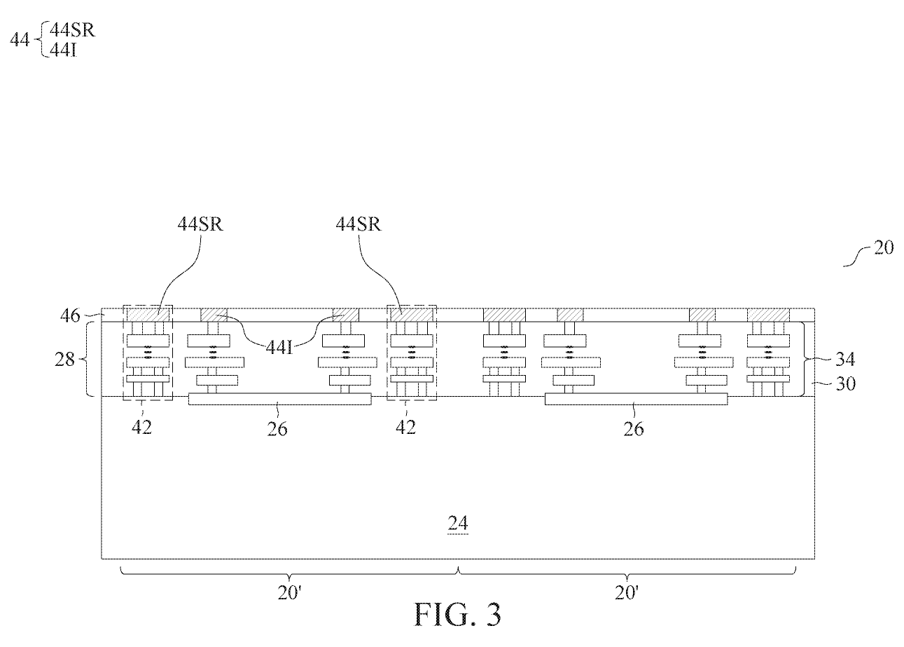

Referring to FIG. 2, interconnect structure 28 is formed. The respective process is illustrated as process 204 in the process flow 200 as shown in FIG. 27. Interconnect structure 28 may include a plurality of dielectric layers 30, which may include an Inter-Layer Dielectric (ILD) and a plurality of Inter-Metal Dielectrics (IMDs) over the ILD. In accordance with some embodiments, the ILD may be formed of or comprise Phospho Silicate Glass (PSG), Boro Silicate Glass (BSG), Boron-doped Phospho Silicate Glass (BPSG), Fluorine-doped Silicate Glass (FSG), silicon oxide, or the like. The ILD may be formed using spin coating, Flowable Chemical Vapor Deposition (FCVD), Plasma Enhanced Chemical Vapor Deposition (PECVD), Low Pressure Chemical Vapor Deposition (LPCVD), or the like.

Conductive features 34 are formed in dielectric layers 30, and are electrically connected to integrated circuit devices 26. In accordance with some embodiments, the conductive features include contact plugs, which are formed in the ILD, and are used to electrically connect integrated circuit devices 26 to overlying metal lines and vias. In accordance with some embodiments, the contact plugs are formed of or comprise a conductive material selected from tungsten, aluminum, copper, titanium, tantalum, titanium nitride, tantalum nitride, alloys therefore, and/or multi-layers thereof

The conductive features 34 further include metal lines and vias formed in the IMD and over the ILD and the contact plugs. The IMDs may be formed of or comprises low-k dielectric materials. The metal lines at a same level are collectively referred to as a metal layer hereinafter. In accordance with some embodiments, interconnect structure 28 includes a plurality of metal layers including metal lines that are interconnected through vias. The metal lines and vias may be formed of or comprise copper or copper alloys, and they can also be formed of other metals.

Interconnect structure 28 includes top conductive (metal) features such as metal lines, metal pads, or vias in a top dielectric layer of dielectric layers 30. In an example embodiment, the top conductive features of interconnect structure 28 include vias. In accordance with some embodiments, the top dielectric layer 30 is formed of a low-k dielectric material similar to the material of lower ones of dielectric layers 30. In accordance with other embodiments, the top dielectric layer 30 is formed of a non-low-k dielectric material, which may include silicon nitride, Undoped Silicate Glass (USG), silicon oxide, or the like. The top conductive features may also be formed of copper or a copper alloy, and may have a dual damascene structure or a single damascene structure.

In accordance with some embodiments, the top dielectric layer 30 may be a passivation layer (sometimes referred to as passivation-1 or pass-1). The passivation layer may be formed of a non-low-k and dense dielectric material having a dielectric constant equal to or greater than the dielectric constant of silicon oxide. The passivation layer may be formed of or comprise an inorganic dielectric material, which may include a material selected from, and is not limited to, silicon nitride, silicon oxide, silicon oxy-nitride, silicon oxy-carbide, or the like, combinations thereof, and/or multi-layers thereof.

FIG. 2 also illustrates the formation of seal ring(s) 42. The respective process is also illustrated as process 204 in the process flow 200 as shown in FIG. 27. While one seal ring 42 is illustrated as an example, there may be one, two, three or more seal rings formed, with the outer seal rings encircling inner seal rings. Seal ring 42 may be electrically floating, electrically grounded, or may be electrically connected to semiconductor substrate 24.

Seal ring 42 includes contact plugs, some metal lines 34, and some vias 36. The contact plugs and the metal lines and vias of the seal ring 42 are formed at the same time and share the same formation processes as the respective features that are used for electrical connections. Each of the contact plugs, metal lines, and vias in seal ring 42 may be physically joined with the overlying and underlying ones of these features to form an integrated seal ring. Each of the contact plugs, metal lines, and vias in seal ring 42 may form a full ring without break therein when viewed in a top view.

In accordance with some embodiments, the contact plugs of seal ring 42 are electrically connected to semiconductor substrate 24. There may be (or may not be) silicide regions between and physically joining the contact plugs and semiconductor substrate 24. In accordance with alternative embodiments, the contact plugs of seal ring 42 are in physical contact with semiconductor substrate 24. In accordance with yet alternative embodiments, the contact plugs of seal ring 42 are spaced apart from semiconductor substrate 24 by a dielectric layer such as a contact etch stop layer (underlying the ILD, not shown), the ILD, and/or the like.

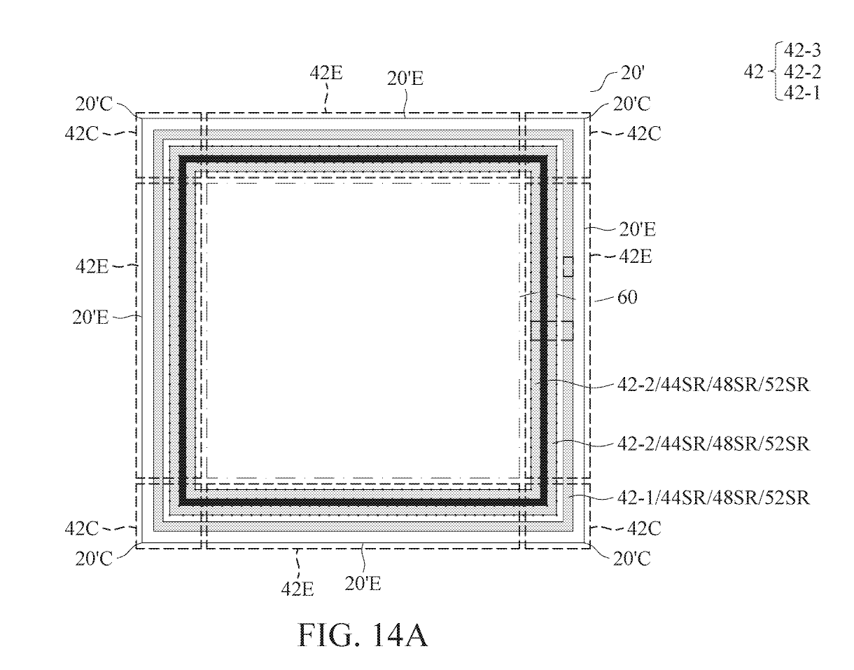

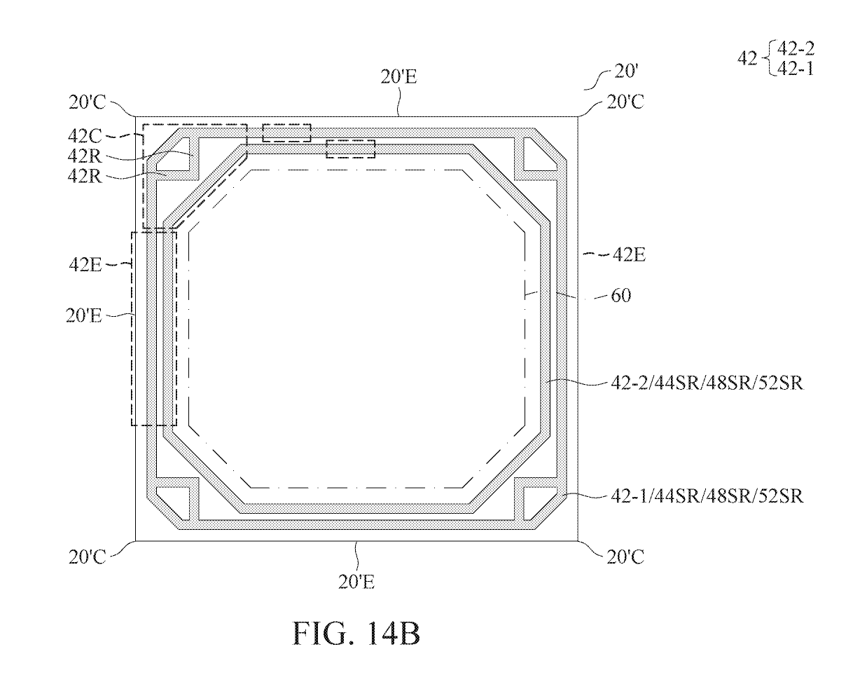

FIGS. 14A and 14B illustrate the top views of a device die 20’ in accordance with some embodiments. Seal ring 42 is formed as a full ring (without breaks therein) including four sections, with each section being close to one of edges of the corresponding device die 20’ and proximate the corresponding scribe lines in the respective wafer 20. Each section is parallel to the nearest edges of device die 20’. Device die 20’ includes four edge portions 42E and four corner portions 42C, with each corner portion 42C interconnecting neighboring edge portions 42E.

In the example as shown in FIG. 14, there are three seal rings 42, which are denoted as seal rings 42-1, 42-2, and 42-3. In accordance with alternative embodiments, there may be a single seal ring or two seal rings.

FIG. 14A illustrates the embodiments in which the seal rings 42 have rectangular shapes. In the embodiments as shown in FIG. 14B, at the corner regions of device die 20’, the seal rings 42 include corner sections. In accordance with some embodiments, seal ring 42 may include some portions 42R at the corners of device die 22 as reinforcement structures.

Seal ring(s) 42 encircle inner region 60, which is used for forming integrated circuit devices 26 (FIG. 1) and the metal lines and vias that are signally and/or electrically connected to the integrated circuit devices 26.

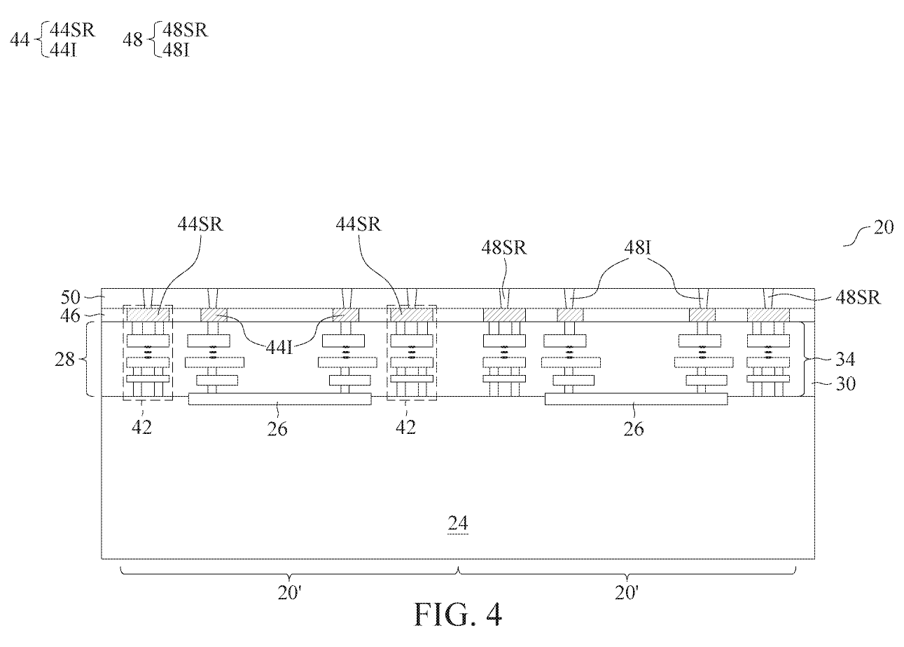

FIG. 3 illustrates the formation of metal pads 44 (including inner metal pads 44I and seal ring metal pads 44SR) and dielectric layer 46. The respective process is illustrated as process 206 in the process flow 200 as shown in FIG. 27. In accordance with some embodiments, the metal pads 44 may comprise aluminum copper, aluminum, copper, or the like. Metal pads 44 are formed in dielectric layer 46 (also referred to as a passivation layer or pass-2), which may comprise silicon oxide, silicon nitride, silicon oxynitride, or the like, or multilayers thereof. In accordance with some embodiments, dielectric layer 46 may comprise portions overlapping the edge portions of metal pads 44.

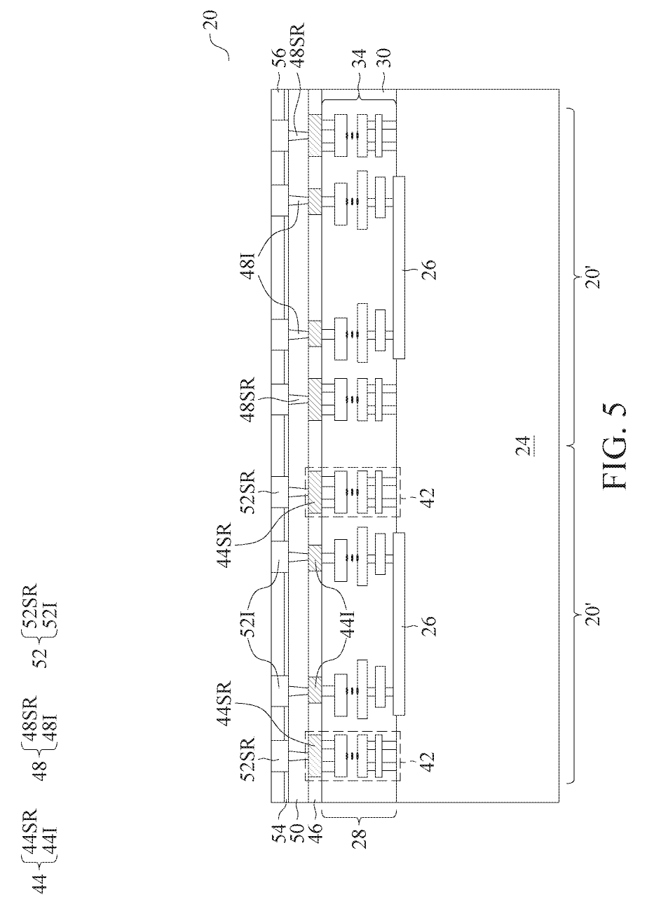

FIG. 4 illustrates the formation of bond vias 48 (including inner vias 48I and seal ring vias 48SR). The respective process is illustrated as process 208 in the process flow 200 as shown in FIG. 27. Bond vias 48 are formed in dielectric layer 50, which may comprise silicon oxide, silicon nitride, silicon oxynitride, or the like. The formation of bond vias 48 may include etching dielectric layer 50 to form via openings, through which the underlying metal pads 44 are revealed, filling the via openings with a conductive material, and performing a planarization process to remove excess portions of the conductive material. In accordance with some embodiments, bond vias 48 may comprise copper, and may comprise diffusion barrier layers, which may comprise Ti, TiN, Ta, TaN, or the like.

FIG. 5 illustrates the formation of bond pads 52 (including inner bond pads 52I and seal ring bond pads 52SR) and bond layer 56. The respective process is illustrated as process 210 in the process flow 200 as shown in FIG. 27. Bond pads 52 are formed in etch stop layer 54 and bond layer 56. Etch stop layer 54 may comprise AlN, AlO, SiOC, or multilayers thereof. Bond layer 56 comprises a silicon-containing dielectric material, which may comprise silicon oxide, silicon nitride, silicon carbide, silicon oxynitride, or the like. The formation of bond pads 52 may include etching etch stop layer 54 and bond layer 56 to form openings, through which the underlying bond vias 48 are revealed, filling the openings with a conductive material, and performing a planarization process to remove excess portions of the conductive material. In accordance with some embodiments, bond pads 52 may comprise copper, and may comprise diffusion barrier layers, which may comprise Ti, TiN, Ta, TaN, or the like.

Metal pads 44 includes inner metal pads 44A and seal ring pad ring 44SR. Inner metal pads 44A are discrete metal pads (which may have the top-view shape of circles, squares, hexagons, or the like). Inner metal pads 44A may include active metal pads that are electrically and/or signally connected to integrated circuit devices 26, and may or may not include dummy metal pads, which may be electrically floating. Seal ring pad ring 44SR may form a full ring, as shown in FIGS. 14A and 14B.

Bond vias 48 include inner bond vias 48I and bond via ring 48SR. Inner bond vias 48I are discrete bond vias (which may have the top-view shape of circles, squares, hexagons, or the like. Inner bond vias 48I may include active metal pads that are electrically and/or signally connected to integrated circuit devices 26, and may or may not include dummy bond vias, which may be electrically floating. In accordance with some embodiments, bond via ring 48SR may form a full ring, as shown in FIGS. 14A and 14B.

Bond pads 52 also include inner bond pads 52I and bond pad ring 52SR. Inner bond pads 52I are discrete bond pads (which may have the top-view shape of circles, squares, hexagons, or the like). Inner bond pads 52I may include active bond pads that are electrically and/or signally connected to integrated circuit devices 26, and may or may not include dummy bond pads, which may be electrically floating. Bond pad ring 52SR may form a full ring, as shown in FIGS. 14A and 14B.

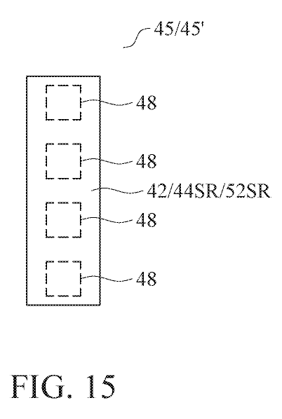

In accordance with alternative embodiments, bond vias 48 are formed as discrete vias that are separated from each other. FIG. 15 illustrates an example of a portion of sear ring 42 and the corresponding discrete vias 48. The illustrated portion may be obtained from regions 45 or 45’ in FIG. 14A.

In accordance with yet alternative embodiments, there are no bond via ring 48SR formed, and there is no discrete vias 48 formed. Bond pad ring 52SR may still be formed to improve bonding strength. Accordingly, in FIG. 15, bond vias 48 are shown as being dashed to indicate that there may be, or may not be vias (or bond via rings). When there is no vias and bond via rings formed, seal ring pad ring 44SR may be electrically disconnected/isolated from bond pad ring 52SR.

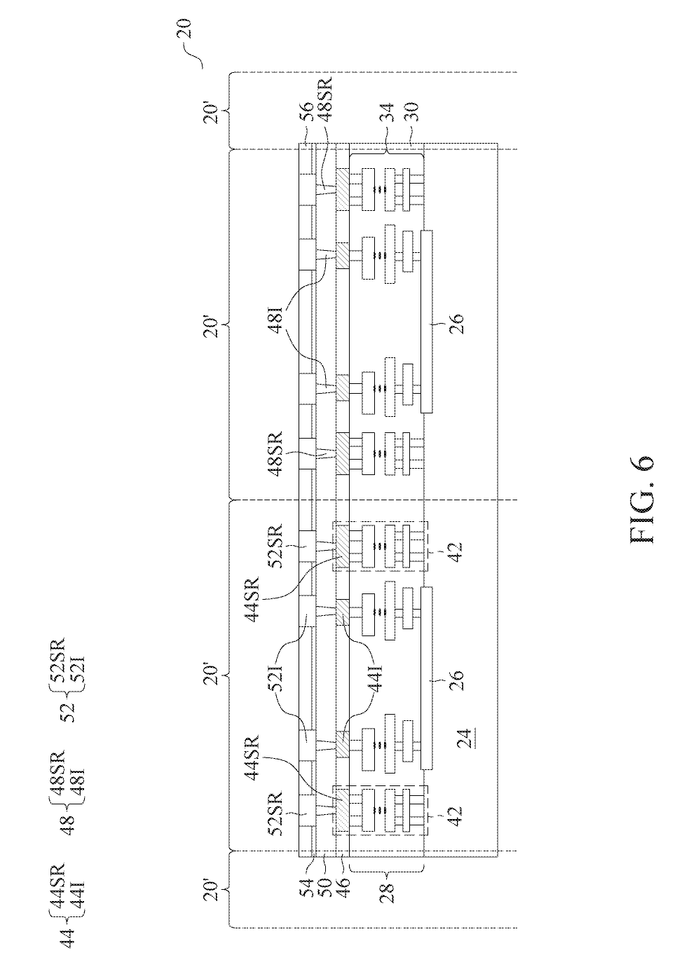

In a subsequent process, as shown in FIG. 6, wafer 20 is singulated, for example, sawed along the scribe lines between device dies 20’ to form package components 20’, which may be device dies 20’ in accordance with some embodiments. The respective process is illustrated as process 212 in the process flow 200 as shown in FIG. 27. In subsequent discussion, device dies 20’ are also referred to as top dies. Although package components 20’ are device dies in accordance with some example embodiments, package components 20’ may also be packages including device dies therein.

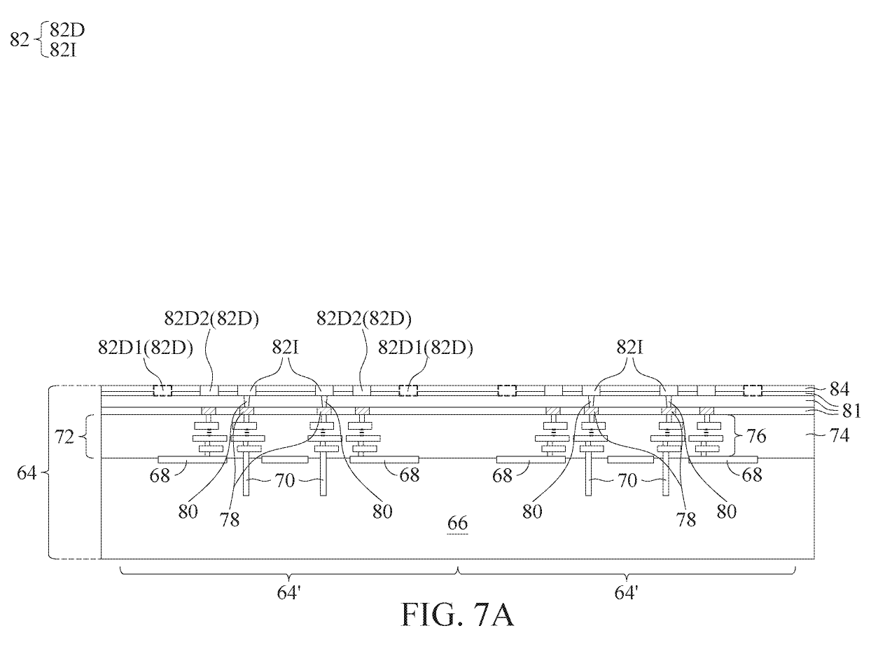

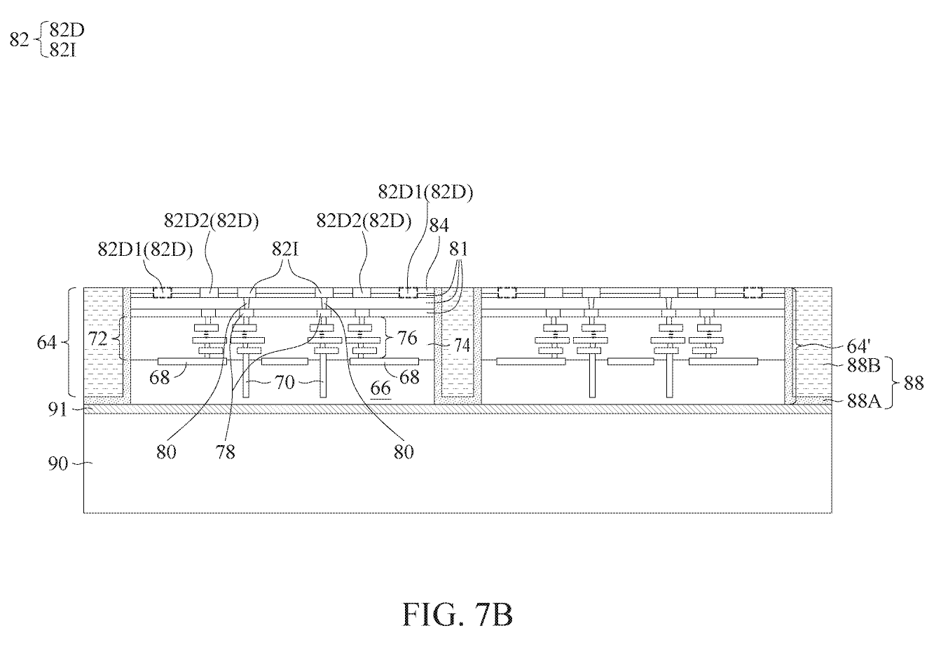

FIG. 7A illustrates a bottom wafer 64. In accordance with some embodiments, bottom wafer 64 is a device wafer, which includes device dies 64’ therein. Device dies 64’ may include active devices and possibly passive devices, which are represented as integrated circuit devices 68. In accordance with some embodiments, integrated circuit devices 68 may include transistors, resistors, capacitors, diodes, and/or the like. The details of integrated circuit devices are not illustrated herein.

In accordance with alternative embodiments, bottom wafer 64 is an interposer wafer, which is free from active devices, and may or may not include passive devices. In accordance with yet alternative embodiments, bottom wafer 64 is or comprises a package such as an Integrated Fan-Out (InFO) Package, a redistribution structure including redistribution lines therein, or the like.

In accordance with some embodiments, bottom wafer 64 includes semiconductor substrate 66 and the features formed at a top surface of semiconductor substrate 66. Semiconductor substrate 66 may be formed of or comprise crystalline silicon, crystalline germanium, crystalline silicon germanium, carbon-doped silicon, a III-V compound semiconductor, or the like.

In accordance with some embodiments, bottom wafer 64 includes through-vias 70 (also referred to as through-silicon vias (TSVs)). TSVs 70 may be electrically connected to the integrated circuit devices 68. In accordance with some embodiments, TSVs 70 extend from the top surface of semiconductor substrate 66 (or a level higher than the top surface of semiconductor substrate 66) to an intermediate level of semiconductor substrate 66. The intermediate level of semiconductor substrate 66 is between the top surface and the bottom surface of semiconductor substrate 66. Each of the TSVs 70 is encircled by a dielectric isolation layer (not shown), which is used for electrically insulate the corresponding TSV 70 from semiconductor substrate 66.

Interconnect structure 72 is formed over semiconductor substrate 66 and integrated circuit devices 26. Interconnect structure 72 may include dielectric layers 74, which may include an ILD and IMDs over the ILD. Interconnect structure 72 further includes contact plugs, metal lines, vias, and the like.

In accordance with some embodiments, metal pads 78, bond vias 80, and bond pads 82 are formed. Dielectric layers 81 and bond layer 84 are also formed. The details of the materials and the formation processes of these features may be essentially the same as the corresponding features in wafer 20, and thus are not discussed herein. Bond pads 82 include inner bond pads 82I and dummy bond pads 82D. Inner bond pads 82I are to be bonded to inner bond pads 52I in a subsequent process, and may be electrically connected to integrated circuit devices 68.

In FIG. 7A, wafer 64 is an unsawed wafer, which has a continuous semiconductor substrate 66 and continuous dielectric layers 74 and 81 and continuous bond layer 84 that continuously extend into a plurality of device dies 64’. In accordance with alternative embodiments, as shown in FIG. 7B, wafer 64 may be a reconstructed wafer including discrete device dies 64’ encapsulated in gap-fill regions 88. The discrete device dies 64’ may be essentially the same as discussed referring to FIG. 7A, which are sawed from wafer 64. The substrate 66 may be thinned. Gap-fill regions 88 may include dielectric liners 88A and dielectric regions 88B, which may comprise silicon nitride and silicon oxide, respectively, in accordance with some embodiments.

Reconstructed wafer 64 may be formed over carrier 90 and release film 91. Carrier 90 is formed of a transparent material, and may be a glass carrier, a ceramic carrier, an organic carrier, or the like. Release film 91 may be formed of a Light-To-Heat-Conversion (LTHC) coating material.

In subsequent discussion, the wafer 64 in FIG. 7A is illustrated as an example, and the discussion may also be applied to the embodiments in which the wafer 64 has the structure as shown in FIG. 7B.

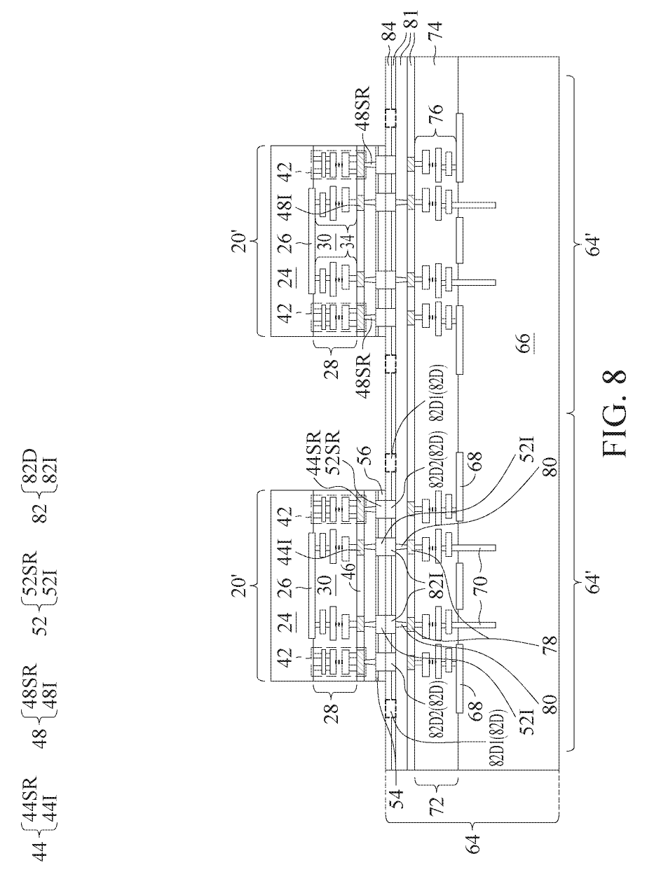

Referring to FIG. 8, device dies 20’ are bonded to bottom wafer 64. The respective process is illustrated as process 214 in the process flow 200 as shown in FIG. 27. The bonding is performed through hybrid bonding. The hybrid bonding includes the bonding of bond layers 56 in device dies 20’ to the bond layer 84 in bottom wafer 64 through fusion bonding (to form Si-O-Si bonds), and the bonding of bond pads 52 in device dies 20’ to the bond pads 82 in bottom wafer 64 through direct metal-to-metal bonding (through metal inter-diffusion).

During the bonding process, the inner bond pads 52I are bonded to the inner bond pads 84I, and the seal ring bond pads 52SR are bonded to the dummy bond pads 82D. There may be, or may not be, additional dummy bond pads 82D not bonded to device dies 20’. The additional bond pads 82D may be bonded to dummy dies, or not bonded.

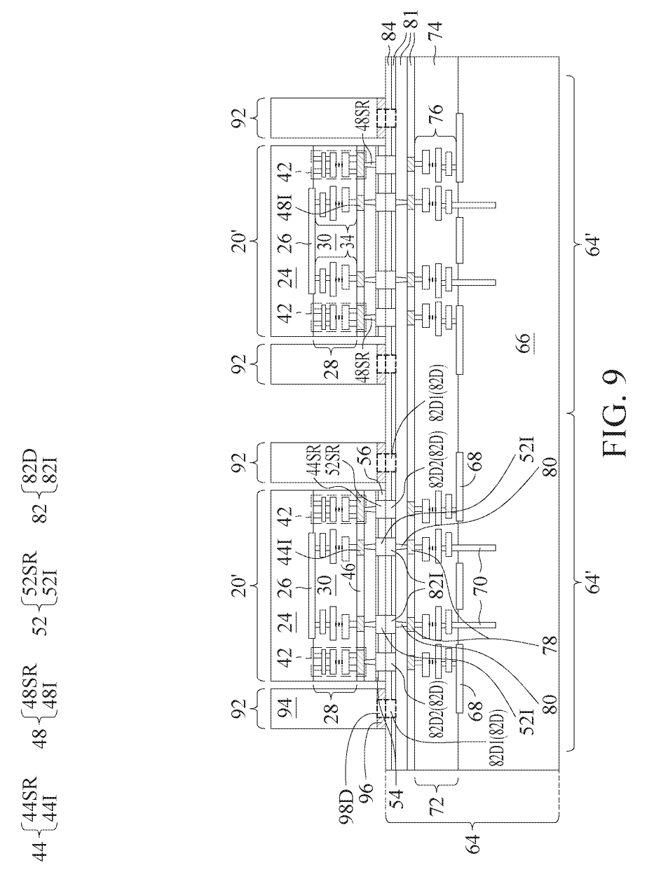

FIG. 9 illustrates the bonding of dummy dies 92 to bottom wafer 64. The respective process is illustrated as process 216 in the process flow 200 as shown in FIG. 27. In accordance with some embodiments, dummy dies 92 comprise substrates 94 and bond layers 96. Substrates 94 may be silicon substrates. Bond layers 96, which are dummy bond pads, may comprise silicon oxide, silicon nitride, silicon carbide, or combinations thereof. Bond pads 98D may be, or may not be, formed in bond layers 96. Bond layers 96 may be bonded to bond layer 84 through fusion bonding. Bond pads 98D may be bonded to dummy bond pads 82D, and may be electrically floating.

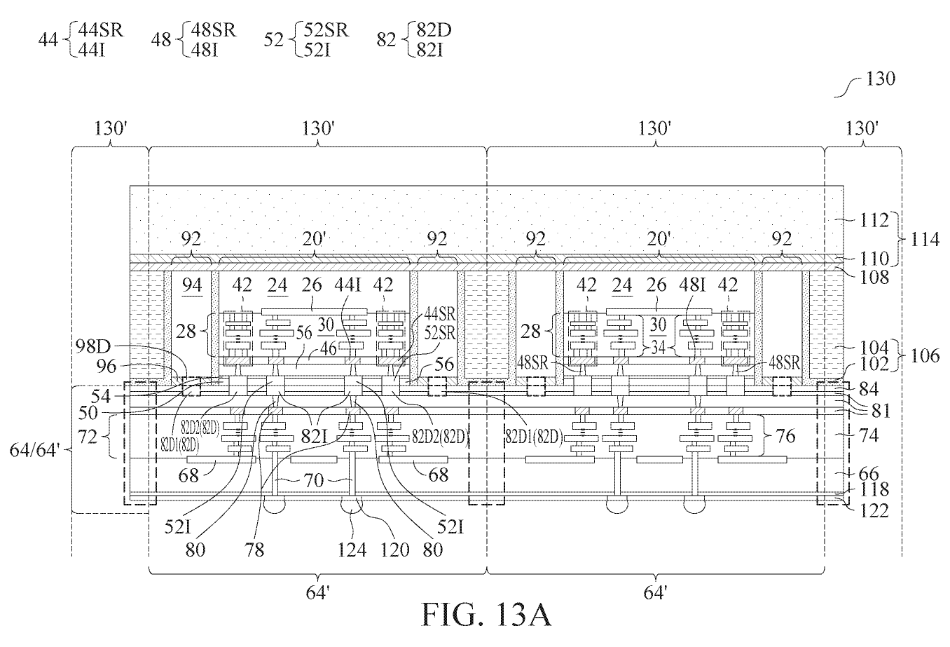

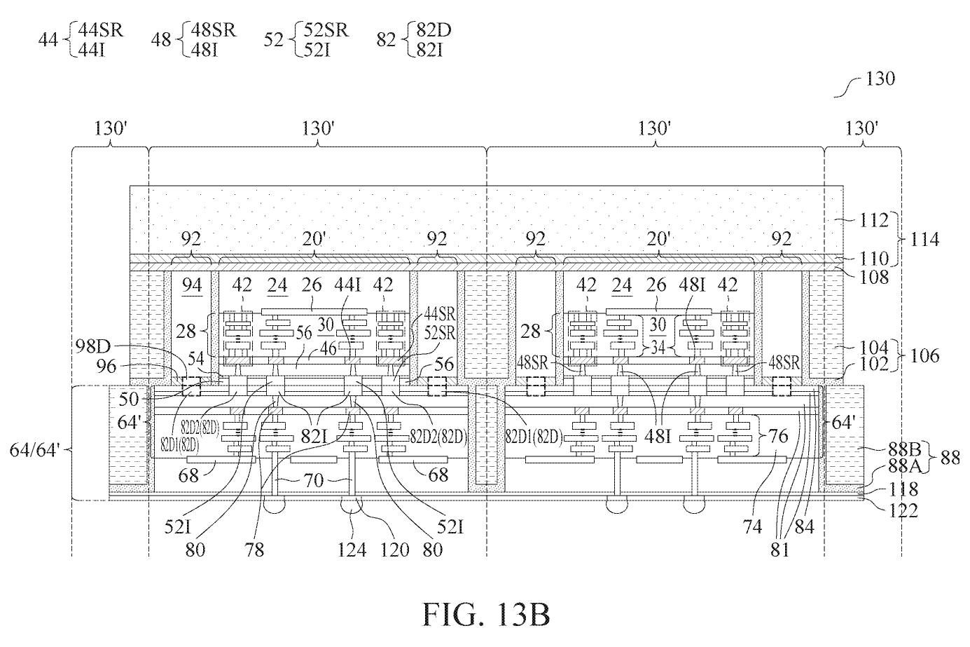

In accordance with some embodiments, dummy bond pads 82D of device dies 64’ include dummy bond pads 82D1 and 82D2. Dummy bond pads 82D2 are bonded to seal ring bond pads 52SR (FIGS. 13A and 13B). Dummy bond pads 82D1 may be bonded to bond pads 98D of dummy dies 92 (FIGS. 13A and 13B).

In accordance with some embodiments, dummy bond pads 82D2 may have a bond pad density (metal density), which density may be the metal density in a unit area. The bond pad density may be defined the same as the bond pad density of seal ring bond pads 52SR, as will be discussed in subsequent paragraphs. The bond pad density of dummy bond pads 82D2 may be higher than (or equal to) the bond pad density of dummy bond pads 82D1, and may be higher than the bond pad density of inner bond pads 82I.

In accordance with some embodiments, seal ring bond pads 52SR may differ from dummy bond pads 82D2 in pitches, lateral dimensions (such as lengths, widths, and/or diameters), top-view areas, top-view shapes, and/or the like. In accordance with some embodiments, each of seal ring bond pads 52SR corresponds to one of the corresponding dummy bond pads 82D2 with a one-to-one correspondence, and the seal ring bond pads 52SR have the same lateral dimensions, same shapes, same pitches, and same layouts as that of dummy bond pads 82D2.

In accordance with yet alternative embodiments, seal ring bond pads 52SR may have different lateral dimensions, different top-view shapes, different pitches, and/or different areas than that of dummy bond pads 82D2. Accordingly, some of seal ring bond pads 52SR may be joined to bond layer 84 instead of joined to dummy bond pads 82D2.

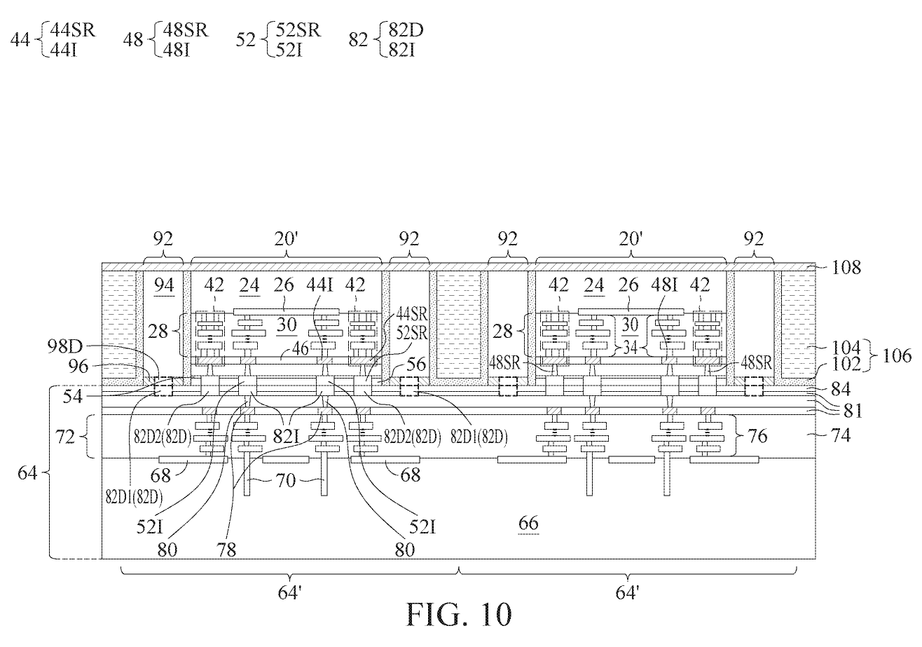

FIG. 10 illustrates the formation of gap-fill regions 106, which include dielectric liners 102 and dielectric layers 104 over the dielectric liners 102. The respective process is illustrated as process 218 in the process flow 200 as shown in FIG. 27. Dielectric liners 102 are formed of a dielectric material that has good adhesion to the sidewalls of device dies 20’ and the top surfaces of bond layer 84. In accordance with some embodiments, dielectric liners 102 are formed of a nitride-containing material such as silicon nitride. Dielectric liners 102 may be formed as conformal layers. The deposition may include a conformal deposition process such as ALD or Chemical Vapor Deposition (CVD).

Dielectric layers 104 are formed of a material different from the material of dielectric liners 102. In accordance with some embodiments, dielectric layers 104 are formed of silicon oxide, while other dielectric materials such as silicon carbide, silicon oxynitride, silicon oxy-carbo-nitride, PSG, BSG, BPSG, or the like may also be used. Dielectric layers 104 may be formed using CVD, HDPCVD, Flowable CVD, spin-on coating, or the like.

Next, a planarization process such as a CMP process or a mechanical grinding process is performed to remove excess portions of dielectric layers 104 and dielectric liners 102, The remaining portions of the dielectric layers 104 and dielectric liners 102 are gap-fill regions 106.

Next, bond layer 108 is formed. Bond layer 108 may comprise silicon oxide, silicon nitride, silicon carbide, or combinations thereof.

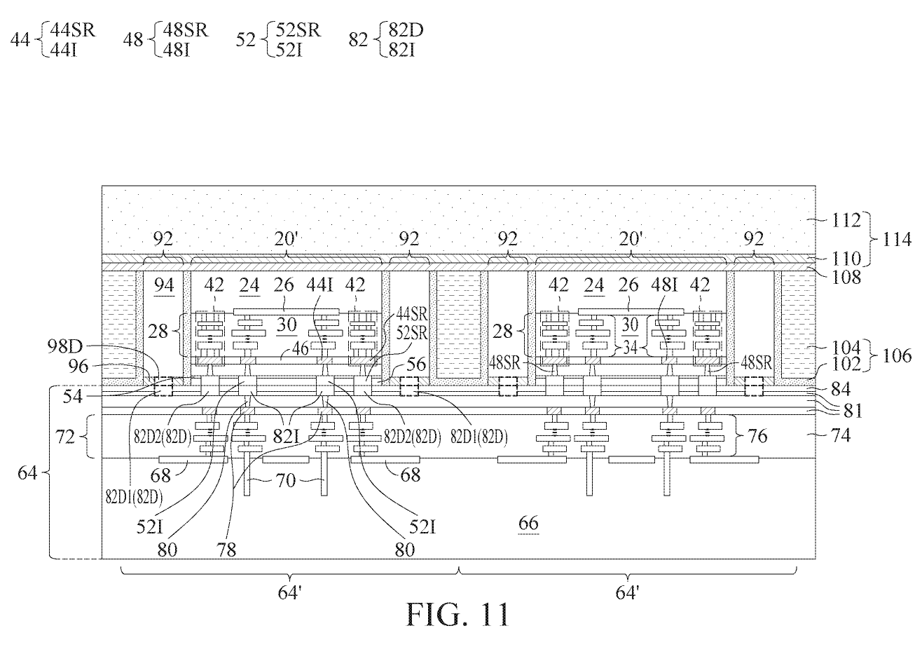

In a subsequent process, as shown in FIG. 11, supporting substrate 114 is bonded to the underlying structure. The respective process is illustrated as process 220 in the process flow 200 as shown in FIG. 27. In accordance with some embodiments, the entire supporting substrate 114 is formed of a homogeneous material (such as silicon), with no other materials and structures therein. In accordance with alternative embodiments, supporting substrate 114 comprises base substrate 112 and bond layer 110. Bond layer 110 may comprise silicon oxide, silicon nitride, silicon carbide, or combinations thereof. Bond layer 110 is bonded to bond layer 108 through fusion bonding.

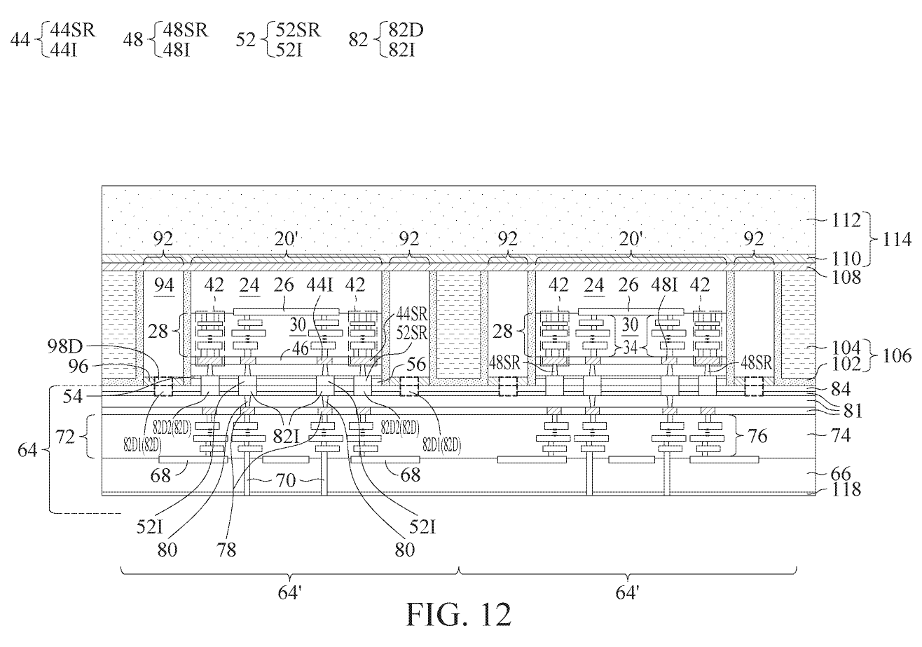

Referring to FIG. 12, a backside grinding process may be performed to thin the substrate 66 of bottom wafer 64. The respective process is illustrated as process 222 in the process flow 200 as shown in FIG. 27. TSVs 70 are thus exposed. A dielectric isolation layer 118 may be formed to embed the bottom ends of TSVs 70 therein. Dielectric isolation layer 118 may comprise silicon oxide, for example.

In accordance with some embodiments, as shown in FIG. 13A, metal pads 120 and dielectric layer 122 are formed on the backside of substrate 66. Electrical connectors 124 are also formed. The respective process is illustrated as process 224 in the process flow 200 as shown in FIG. 27. Electrical connectors 124 may comprise metal pillars, solder regions, or the like. Reconstructed wafer 130 is thus formed. In a subsequent process, reconstructed wafer 130 is singulated (sawed) to form discrete packages 130’. The respective process is illustrated as process 226 in the process flow 200 as shown in FIG. 27.

FIG. 13B illustrates an alternative embodiment similar to what is shown in FIG. 13B, except that a reconstructed wafer as shown in FIG. 7B is adopted, and discrete device dies 64’ are encapsulated in gap-fill regions 88.

In subsequent processes, a package 130’ may be bonded with another package component (not shown), such as an interposer, a package substrate, a printed circuit board, a package, or the like. The electrical connectors 124 in package 130’ may be bonded to the electrical connectors (such as bond pads or metal pillars) of the other package component through solder bonding.

FIGS. 14A and 14B illustrate the top (or bottom) views of device die 20’ in accordance with some embodiments. Device die 20’ has edges 20’E and corners 20’C. There may be a single seal ring 42 (such as seal ring 42-1) or a plurality of seal rings 42 (such as seal rings 42-1, 42-2, and 42-3) formed proximate the peripheral of the device die 20’, with the outer seal ring 42-1 encircling the respective inner seal ring(s) 42-2 and 32-3. The subsequent discussion may refer to one of the seal rings such as the outer seal ring 42-1 as an example, and the discussion also applies to other seal rings 42-2, 42-3, and the like. Each of seal ring 42 may include four edge portions/sections 42E, which are parallel to the nearest edges 20’E, and four corner portions 42C, which interconnect neighboring edge portions 42E.

As aforementioned, seal ring(s) 42 encircle inner region 60, which is used for forming integrated circuit devices 26 (FIG. 8) and their connecting conductive features. Seal ring 42 may be electrically floating, electrically grounded, or may be electrically connected to semiconductor substrate 24.

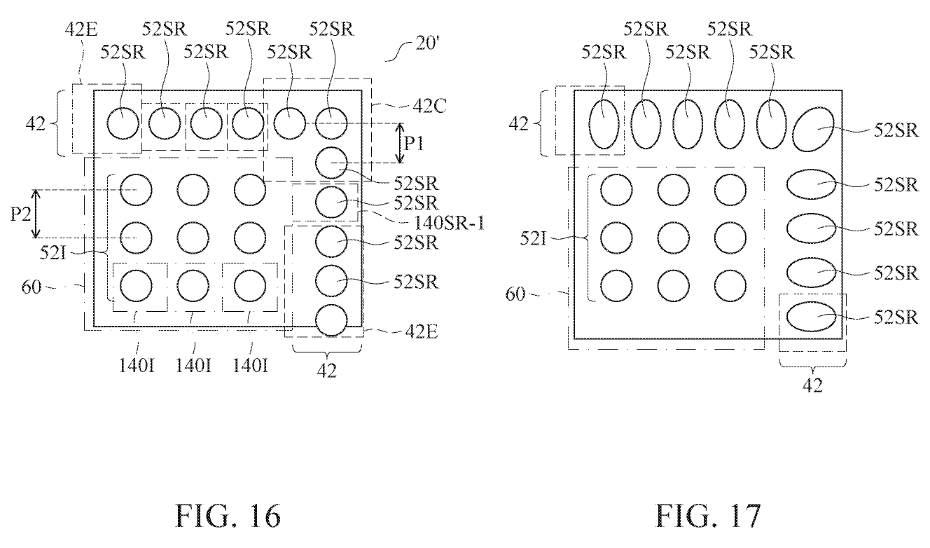

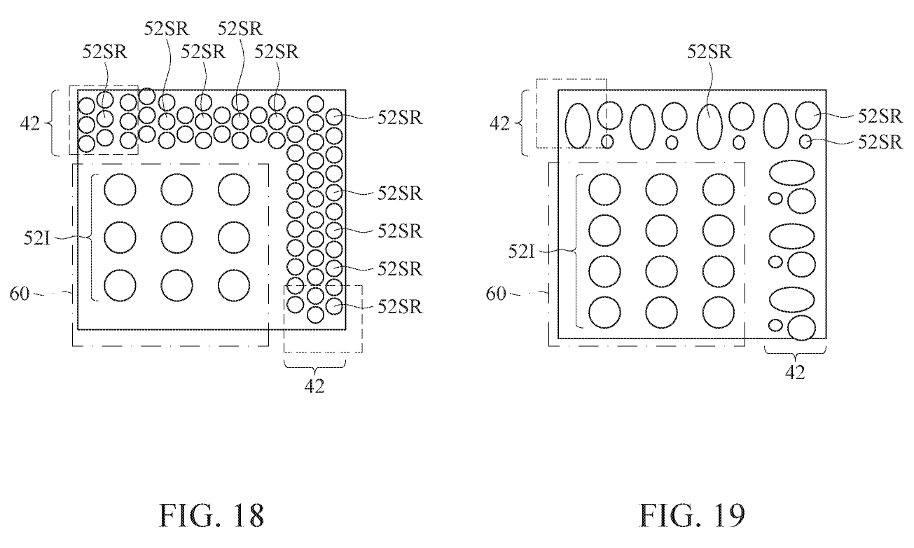

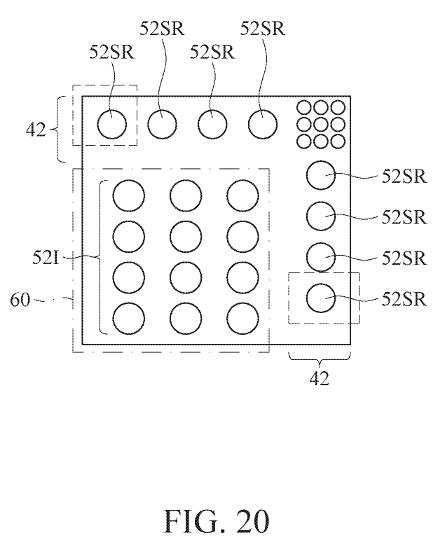

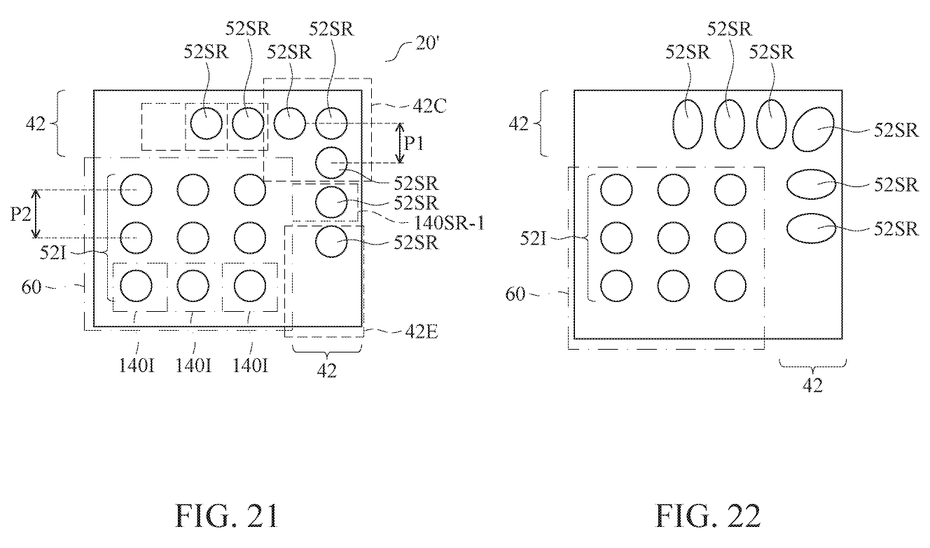

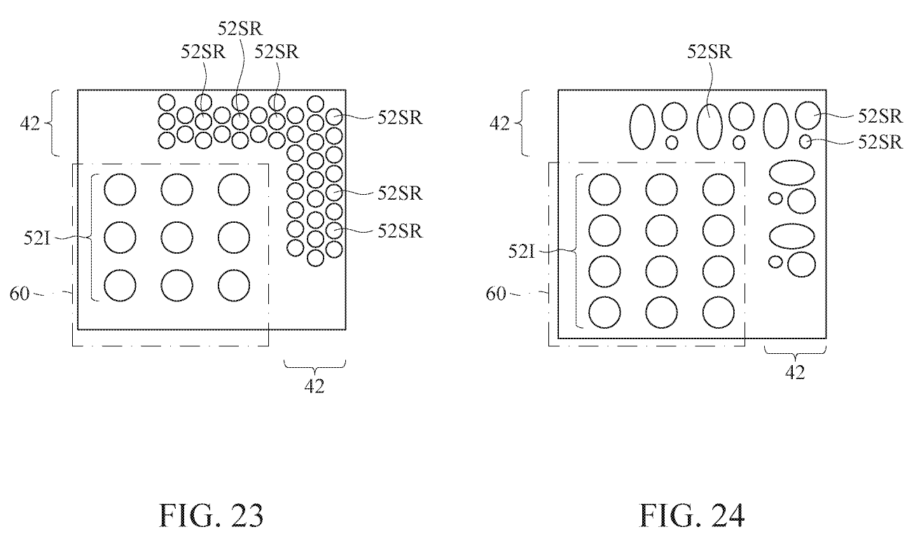

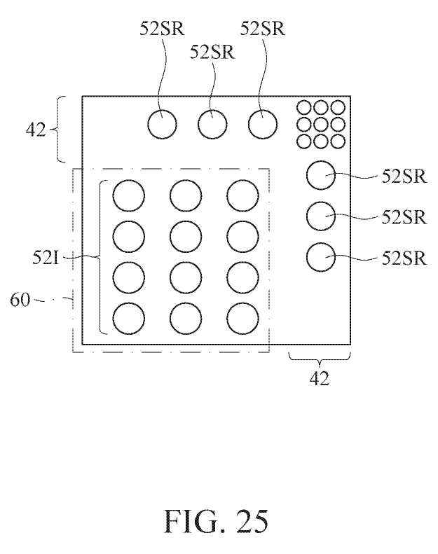

FIGS. 16 - 20 illustrate the top views of inner bond pads 52I and seal ring bond pads 52SR in accordance with some embodiments. In the illustrated embodiments, one seal ring 42-1 is illustrated, while the discussion may also be applied to other seal rings such as seal rings 42-2 and 42-3.

FIGS. 16-20 illustrate one corner region of device die 20’ in FIG. 14A. Inner region 60 is on the inner side of, and is encircled by, seal ring 42-1. While not shown, seal rings 42-2 and/0r 42-3 (FIG. 14) may be, or may not be, formed between inner region 60 and seal ring 42-1, as illustrated in an example. There are a plurality of inner bond pads 52I and a plurality of bond pads 52SR formed. Inner bond pads 52I may have the same top-view size as or different sizes than bond pads 52SR. Inner bond pads 52I may also have the same top-view area as or different areas than bond pads 52SR. Inner bond pads 52I and bond pads 52SR may have any top-view shape including, and not limited to, circular shapes (as shown in FIGS. 14A, 14B and 15-25), rectangular shapes, hexagonal shapes, octagonal shapes, or the like.

In accordance with some embodiments, the inner bond pads 52I have inner pad density D_{bI}. The seal ring bond pads 52SR have seal ring pad density D_{52SR}. Throughout the description, a pad density of bond pads may be defined by calculating the pad density of the repeating units of the bond pads in the top view of the corresponding chip region that have the bond pads therein. For example, as shown in FIG. 16, the illustrated array of inner bond pads 52I may be divided into a plurality of repeating units 140I, each including a metal pad 52I therein. The plurality of repeating units 140I, when joined side-by-side, form a continuous chip area including a plurality of inner bond pads 52I therein. Depending on how the metal pads are laid out, the repeating units 140I may have the rectangular (which may be squares) as illustrated, or hexagonal shape when the bond pads are laid out to have a beehive pattern. The inner pad density D_{52I} of inner bond pads 52I may be calculated as the ratio of the top-view area of an inner bond pad 52I in a repeating unit 140I to the total area of the repeating unit 140I.

The repeating unit 140SR of the seal ring bond pad 52SR may be defined as extending to the opposing edges of seal ring 42-1 in the top view, wherein the opposing edges are the long edges. For example, for the repeating unit 140SR-1, the repeating unit extends to the left and right edge of seal ring 42-1. Similarly, the repeating units 140SR, when joined, will form a continuous region having a plurality of seal ring bond pad 52SR therein. The seal ring pad density D_{52SR} of seal ring bond pads 52SR may be calculated as the ratio of the top-view area of a seal ring bond pad 52SR in a repeating unit 140SR to the total area of the repeating unit 140SR.

Alternatively, the inner pad density of a chip area including a plurality of inner bond pads 52I may be calculated as the average pad density of a large continuous chip area including a plurality of inner bond pads 52I, which may be, for example, more than 10, 20, 50, or 100 inner bond pads 52I. The chip area should also extend outwardly from the outmost ones of inner bond pads 52I for distances that are equal to a half the pitch of the inner bond pads 52I.

Alternatively, the seal ring pad density of a chip area including a plurality of seal ring bond pads 52SR may be calculated as the average pad density of a large continuous chip area including a plurality of seal ring pads 52SR, which may be, for example, more than 5, 10, 20, or 50 seal ring pads 52SR. The chip area should also extend outwardly to the opposing edges of seal ring 42-1 in the top view.

In accordance with some embodiments, the inner pad density D_{52I} may be in the range between about 5 percent (0.05) and about 20 percent (0.2). the seal ring pad density D_{52SR} is greater than the inner pad density D_{52I}. The difference (D_{52SR} - D_{52I}) may be in the range between about 5 percent and about 30 percent (0.3). In accordance with some embodiment, the seal ring pad density D_{52SR} may be in the range between about 10 percent (0.1) and about 50 percent (0.5).

Increasing the seal ring pad density D_{52SR} to be higher than the inner pad density D_{52I} is advantageous for improving bonding strength. It is appreciated that due to the warpage of wafers and chips, the corner region and the edge regions of the device dies 20’ are likely to have non-bond defects, which means the failed bonding of bond pads. Increasing the seal ring pad density D_{52SR} has the effect of reducing non-bonds due to the high bond strength of bond pads than fusion bonding.

The increase of the seal ring pad density D_{52SR} may be achieved through a plurality of embodiments or the combination of the embodiments. For example, in FIG. 16, seal ring bond pads 52SR have the same top-view shape and the same top-view area as inner bond pads 52I. The increase of the seal ring pad density D_{52SR} may be achieved by reducing the pitch P1 of the seal ring bond pads 52SR to be smaller than the pitch P2 of the inner bond pads 52I. For example, pitch ratio P1/P2 may be in the range between about 0.7 and about 0.9.

FIG. 17 illustrates some embodiments in which seal ring bond pads 52SR are larger than inner bond pads 52I. The pitch of seal ring bond pads 52SR may be equal to (or greater than or smaller than) the pitch of inner bond pads 52I. The top-view shapes of seal ring bond pads 52SR may also be the same as or different from the top-view shapes of inner bond pads 52I. For example, in the embodiments in FIG. 17, seal ring bond pads 52SR may be stretched as being elongated to increase their size and top-view areas.

FIG. 18 illustrates some embodiments in which the seal ring bond pads 52SR are made smaller, but are packed densely to increase seal ring pad density D_{52SR} to be greater than the inner pad density D_{52I}. FIG. 19 illustrates some embodiments in which the seal ring bond pads 52SR includes a plurality of shapes and/or sizes. The seal ring bond pads 52SR in a small chip area are illustrated, and the patterns of the seal ring bond pads 52SR may be repeated

FIG. 20 illustrates some embodiments in which the seal ring bond pads 52SR over corner portions 42C of the seal ring 42-1 have a greater metal pad density (with the same or different top-view) than the seal ring bond pads 52SR in edge regions of device die 20’. The difference of the metal pad densities may be greater than about 2 percent, and may be in the range between about 2 percent and about 10 percent. The seal ring bond pads 52SR over the edge portions 42E of the seal ring 42-1 have greater metal pad density (with the same or different top-view) than in inner region 60 of device die 20’, and the difference of the metal pad density may be greater than about 2 percent, and may be in the range between about 2 percent and about 10 percent.

FIGS. 21-25 illustrate the embodiments similar to the embodiments in FIGS. 16-20, except that in FIGS. 16-20, seal ring bond pads 52SR are formed throughout the entire seal rings 42, for example, with substantially a uniform metal pad density, while in FIGS. 21-25, , seal ring bond pads 52SR are formed in the corner regions of the respective seal rings 42, but are not formed in the edge portions of the seal rings 42.

In accordance with some embodiments, the seal ring bond pads 52SR are laid out throughout the corner portions 42C and edge portions 42E (FIG. 14) of seal ring 42. In accordance with alternative embodiments, the seal ring bond pads 52SR are laid out in the corner regions, while over the edge portions 42E of seal ring, there are no seal ring bond pads 52SR. For example, in FIGS. 16-20, the seal ring bond pads 52SR over edge portions 42E will not be formed.

Also, while the bond pads with the higher pad density are described as the seal ring bond pads in the example embodiments, the e bond pads with the higher pad density (and have the patterns as shown in FIGS. 16-20) may also be the bond pads that are connected to integrated circuit devices.

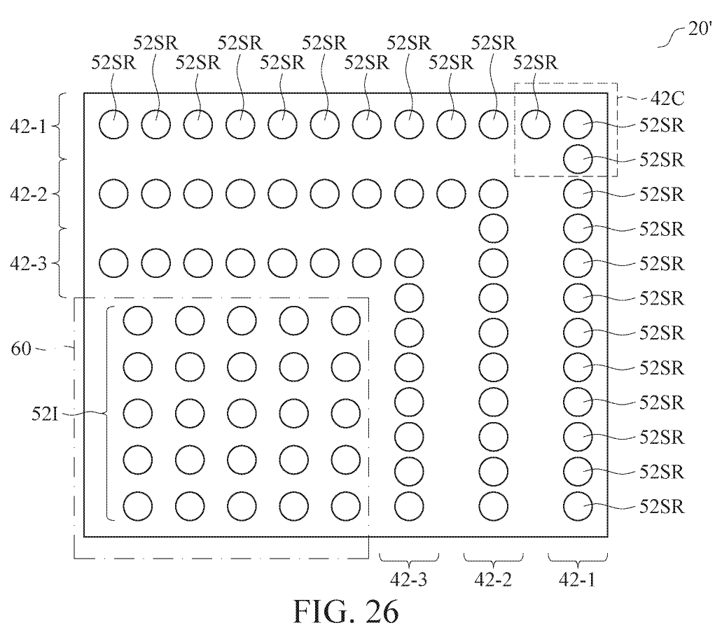

FIG. 26 illustrates some embodiments in which a plurality of seal rings such as seal rings 42-1, 42-2, and 42-3 are formed. In accordance with some embodiments, the seal ring bond pads 52SR overlapping all of seal rings 42 have a same pad density, which is greater than the pad density of inner bond pads 52I. In accordance with alternative embodiments, the seal ring bond pads 52SR overlapping outer seal rings (such as seal ring 42-1) are increasingly greater than the seal ring bond pads 52SR over the respective inner seal rings (such as seal ring 42-2), and all are greater than the pad density of inner bond pads 52I.

In accordance with yet alternative embodiments, the seal ring bond pads 52SR overlapping the outmost seal ring 42-1 has a greater pad density than the seal ring bond pads 52SR overlapping an inner seal ring 42-2, and both are greater than the pad density of inner bond pads 52I. There are, however, no bond pads overlapping seal ring 42-3.

The embodiments of the present disclosure have some advantageous features. By increasing the pad density of the seal ring bond pads, the non-bond issues may be reduced or eliminated. The improvement of the bonding strength does not require extra manufacture process and does not incur the increase in the manufacturing cost.

In accordance with some embodiments, a method comprises forming a plurality of dielectric layers; forming a seal ring comprising a plurality of metal rings, each extending into one of the plurality of dielectric layers; forming a plurality of metal lines and vias in the plurality of dielectric layers, wherein the plurality of metal lines and vias are in an inner region encircled by the seal ring; forming a plurality of seal ring bond pads over the seal ring, wherein the plurality of seal ring bond pads have a first pad density; and forming a plurality of inner bond pads in the inner region, wherein at least parts of the plurality of inner bond pads are electrically connected to the plurality of metal lines and vias, and wherein the plurality of inner bond pads have a second pad density lower than the first pad density. In an embodiment, the seal ring is in a die, and the seal ring comprises portions proximate edges of the die.

In an embodiment, the seal ring comprises four edges and four corners, and wherein the plurality of seal ring bond pads comprise a plurality of corner bond pads at one of the four corners of the die. In an embodiment, the seal ring comprises four edges and four corners, and wherein the plurality of inner bond pads comprise a plurality of seal ring bond pads near one of the four edges of the die. In an embodiment, the method further comprises performing a sawing process, wherein the seal ring is sawed into a die.

In an embodiment, the method further comprises performing a bonding process, wherein the plurality of seal ring bond pads and the plurality of inner bond pads are bonded to additional bond pads of a package component. In an embodiment, the plurality of seal ring bond pads and the plurality of inner bond pads are bonded to the additional bond pads through direct metal-to-metal bonding; and a first dielectric layer embedding the plurality of seal ring bond pads and the plurality of inner bond pads is bonded to a second dielectric layer embedding the additional bond pads through fusion bonding.

In an embodiment, the plurality of seal ring bond pads have a first top-view area and a first pitch, and the plurality of inner bond pads have a second top-view area equal to the first top-view area, and a second pitch greater than the first pitch. In an embodiment, the plurality of seal ring bond pads have a first top-view area and a first pitch, and the plurality of inner bond pads have a second top-view area smaller than the first top-view area, and a second pitch equal to the first pitch.

In accordance with some embodiments, a method comprises forming a wafer comprising forming a seal ring over a substrate; forming a first bond layer over the seal ring; forming a plurality of seal ring bond pads in the first bond layer, wherein the plurality of seal ring bond pads have a first pad density; and forming a plurality of inner bond pads in the first bond layer, wherein in a top view of the seal ring, the plurality of inner bond pads are encircled by the seal ring, and the plurality of inner bond pads have a second pad density lower than the first pad density; sawing the wafer to form a plurality of dies, wherein the seal ring is in a first die of the plurality of dies, and wherein portions of the seal ring are proximate edges of the first die; and bonding the first die to a second die of a second wafer.

In an embodiment, the bonding comprises bonding the first bond layer to a second bond layer of the second die through fusion bonding; and bonding the plurality of seal ring bond pads and the plurality of inner bond pads to additional bond pads of the second die. In an embodiment, the plurality of seal ring bond pads have same sizes as, and a smaller pitch than, the plurality of inner bond pads. In an embodiment, the method further comprises bonding a dummy die to the second die.

In an embodiment, the method further comprises, after the bonding, forming gap-fill regions encircling the first die therein. In an embodiment, the method further comprises bonding a supporting substrate to the gap-fill regions and the first die. In an embodiment, the method further comprises sawing the second wafer to form a package, wherein the first die and the second die are in the package.

In accordance with some embodiments, a structure comprises a bottom die comprising a first bond layer; and a first plurality of bond pads in the first bond layer; and a top die comprising a second bond layer joined to the first bond layer; and a second plurality of bond pads in the second bond layer and joined to the first plurality of bond pads, wherein the second plurality of bond pads comprise a plurality of inner bond pads in an inner region of the top die, wherein the plurality of seal ring bond pads have a first pad density; and a plurality of seal ring bond pads in a peripheral region of the top die, wherein the inner region is encircled by the peripheral region, wherein the plurality of seal ring bond pads have a second pad density greater than the first pad density; a seal ring over and electrically connected to the plurality of seal ring bond pads; and a plurality of metal lines and vias over and electrically connected to the plurality of inner bond pads.

In an embodiment, the plurality of seal ring bond pads have a smaller pitch than the plurality of inner bond pads. In an embodiment, the plurality of seal ring bond pads have a same size as the plurality of inner bond pads. In an embodiment, the plurality of seal ring bond pads are larger (with greater dimensions such as width, lengths, or diameters), and/or have greater areas, than the plurality of inner bond pads when viewed in a top view of the respective structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of dielectric layers;
forming a seal ring comprising a plurality of metal rings, each extending into one of the plurality of dielectric layers;
forming a plurality of metal lines and vias in the plurality of dielectric layers, wherein the plurality of metal lines and vias are in an inner region encircled by the seal ring;
forming a plurality of seal ring bond pads over the seal ring, wherein the plurality of seal ring bond pads have a first pad density; and
forming a plurality of inner bond pads in the inner region, wherein at least parts of the plurality of inner bond pads are electrically connected to the plurality of metal lines and vias, and wherein the plurality of inner bond pads have a second pad density lower than the first pad density.

2. The method of claim 1, wherein the seal ring is in a die, and the seal ring comprises portions proximate edges of the die.

3. The method of claim 2, wherein the seal ring comprises four edges and four corners, and wherein the plurality of seal ring bond pads comprise a plurality of corner bond pads at one of the four corners of the die.

4. The method of claim 2, wherein the seal ring comprises four edges and four corners, and wherein the plurality of seal ring bond pads comprise a plurality of edge bond pads near one of the four edges of the die.

5. The method of claim 1 further comprising performing a sawing process, wherein the seal ring is sawed into a die.

6. The method of claim 1 further comprising performing a bonding process, wherein the plurality of seal ring bond pads and the plurality of inner bond pads are bonded to additional bond pads of a package component.

7. The method of claim 6, wherein:
the plurality of seal ring bond pads and the plurality of inner bond pads are bonded to the additional bond pads through direct metal-to-metal bonding; and
a first dielectric layer embedding the plurality of seal ring bond pads and the plurality of inner bond pads is bonded to a second dielectric layer embedding the additional bond pads through dielectric-to-dielectric bonding.

8. The method of claim 1, wherein the plurality of seal ring bond pads have a first top-view area and a first pitch, and the plurality of inner bond pads have a second top-view area equal to the first top-view area, and a second pitch greater than the first pitch.

9. The method of claim 1, wherein the plurality of seal ring bond pads have a first top-view area and a first pitch, and the plurality of inner bond pads have a second top-view area smaller than the first top-view area, and a second pitch equal to the first pitch.

10. A method comprising:
forming a wafer comprising:
forming a seal ring over a substrate;
forming a first bond layer over the seal ring;
forming a plurality of seal ring bond pads in the first bond layer, wherein the plurality of seal ring bond pads have a first pad density; and
forming a plurality of inner bond pads in the first bond layer, wherein in a top view of the seal ring, the plurality of inner bond pads are encircled by the seal ring, and the plurality of inner bond pads have a second pad density lower than the first pad density;
sawing the wafer to form a plurality of dies, wherein the seal ring is in a first die of the plurality of dies, and wherein portions of the seal ring are proximate edges of the first die; and
bonding the first die to a second die of a second wafer, wherein the plurality of seal ring bond pads are physically joined to additional bond pads of the second die through metal-to-metal bonding, and wherein the plurality of seal ring bond pads differ from the additional bond pads of the second die in at least one of pitches, lateral dimensions, top-view shapes, and top-view areas.

11. The method of claim 10, wherein the bonding comprises:
bonding the first bond layer to a second bond layer of the second die through dielectric-to-dielectric bonding; and
bonding the plurality of seal ring bond pads and the plurality of inner bond pads to the additional bond pads of the second die.

12. The method of claim 10, wherein the plurality of seal ring bond pads have same sizes as, and a smaller pitch than, the plurality of inner bond pads.

13. The method of claim 10, wherein in a top view of the wafer, the plurality of seal ring bond pads have different shapes or different sizes.

14. The method of claim 10 further comprising, after the bonding, forming gap-fill regions encircling the first die therein.

15. The method of claim 14 further comprising bonding a supporting substrate to the gap-fill regions and the first die.

16. The method of claim 10, wherein the plurality of seal ring bond pads are electrically connected to the seal ring.

17. A structure comprising:
a first die comprising:
a plurality of inner bond pads in an inner region of the first die, wherein the plurality of inner bond pads have a first pad density;
a plurality of seal ring bond pads in a peripheral region of the first die, wherein the inner region is encircled by the peripheral region, wherein the plurality of seal ring bond pads have a second pad density greater than the first pad density;
a seal ring over the plurality of seal ring bond pads; and
a plurality of metal lines and vias over and electrically connected to the plurality of inner bond pads.

18. The structure of claim 17, wherein the plurality of seal ring bond pads have a smaller pitch than the plurality of inner bond pads.

19. The structure of claim 18, wherein the plurality of seal ring bond pads have a same lateral dimension as the plurality of inner bond pads.

20. The structure of claim 17, wherein the plurality of seal ring bond pads have a greater width than the plurality of inner bond pads in a top view of the structure.
